(19) United States
(12) Patent Application Publication
(10) Pub. No.: US 2009/0321864 A1
(43) Pub. Date: Dec. 31, 2009

(54) CMOS IMAGE SENSOR AND METHOD FOR MANUFACTURING THE SENSOR

(76) Inventor: Min-Kyu Kang, Daiseo-gu (KR)

Correspondence Address: SHERR & VAUGHN, PLLC, 620 HERNDON PARKWAY, SUITE 320, HERNDON, VA, 20170, US

(21) Appl. No.: 12/483,540

(22) Filed: Jun. 12, 2009

(30) Foreign Application Priority Data
Jun. 27, 2008 (KR) 10-2008-0061516

(51) Int. Cl. H01L 31/0232; G03B 27/42

(52) U.S. Cl. 257/432; 438/70; 355/53; 257/E31.127

(57) ABSTRACT

A CMOS image sensor manufacturing method may include forming an interlayer insulating film over a semiconductor substrate in which a plurality of photodiodes are formed, forming a plurality of color filter layers corresponding to the photodiodes over the interlayer insulating film, forming a flattening layer over an entire surface of the semiconductor substrate including the respective color filter layers, forming gap insulating films over the flattening layer and over boundaries of the color filter layers, and forming micro-lenses over the flattening layer between the gap insulating films, to correspond to the respective photodiodes.

The present application claims priority under 35 U.S.C. 119 to Korean Patent Application No. 10-2008-0061516 (filed on Jun. 27, 2008), which is hereby incorporated by reference in its entirety.

### BACKGROUND

Generally, image sensors are semiconductor devices which convert optical images into electric signals. Such image sensors may be divided into broad categories including Charge Coupled Device (CCD) image sensors and a Complementary Metal Oxide Semiconductor (CMOS) image sensors.

A CMOS image sensor may include a photodiode to sense irradiated light, and a CMOS logic circuit to process the sensed light into electric signals for data formation. The greater the quantity of light received by a photodiode, the greater the photo-sensitivity of the image sensor.

Different technologies may be used to achieve enhanced photo-sensitivity, for example to increase a so-called “Fill Factor,” which is the ratio of the area occupied by a photodiode to the entire area of the image sensor, or to change a path of light to condense all the incident light onto the photodiode, and not the non-photosensitive regions surrounding the photodiode. A representative example of the condensing technologies is a method for forming a micro-lens, in which a related convex micro-lens is formed over a photodiode by use of a high light transmittance material. The micro-lens serves to refract incident light and allows a greater quantity of light to be irradiated to the photodiode. In this case, light approximately parallel to an optical axis of the micro-lens is refracted by the micro-lens, thereby being focused on a predetermined position on the optical axis.

In the fabrication process of a device used an image sensor, the number of photodiodes for image-reception determines image resolution. For this reason, pixels have been made to have a smaller size and to be provided in a greater number. With a smaller size and greater number of pixels, an external image to be input into an image plane is focused via the micro-lens.

With respect to a color filter, color filter layers of a primary color type or a complementary color type are formed for color separation. More specifically, to achieve color separation and consequently, color reproduction, red, green and blue color filter layers in the case of the primary color type and cyan, yellow and magenta color filter layers in the case of the complementary color type are formed in an on-chip manner.

It is noted that the micro-lens is provided to enhance condensing efficiency, to achieve efficient utilization, i.e. maximum utilization of incident light. Such a micro-lens may be formed by photoresist thermal reflow. However, if the photoresist thermal reflow is carried out to maximize the size of the micro-lens for concentration of a greater quantity of light, it may cause a bridge between neighboring micro-lenses. Therefore, a certain degree of Critical Dimension (CD) must be provided in terms of good uniformity.

The CMOS image sensor is classified into a 3T type, 4T type, 5T type, etc., based on the number of transistors. A 3T type CMOS image sensor includes one photodiode and three transistors, and a 4T type CMOS image sensor includes one photodiode and four transistors. Below, a lay-out with respect to a unit pixel of the 3T type CMOS image sensor will be described.

FIG. 1 is an equivalent circuit diagram of a general 3T type CMOS image sensor, and FIG. 2 is a lay-out diagram illustrating a unit pixel of the general 3T type CMOS image sensor.

The unit pixel of the general 3T type CMOS image sensor, as shown in FIG. 1, includes one photodiode PD and three nMOS transistors T1, T2 and T3. A cathode of the photodiode PD is connected to a drain of a first nMOS transistor T1 and a gate of a second nMOS transistor T2. The sources of the first and second nMOS transistors T1 and T2 are connected to a power line for supply of a reference voltage VR. A gate of the first nMOS transistor T1 is connected to a reset line for supply of a reset signal RST. Also, a source of a third nMOS transistor T3 is connected to a drain of the second nMOS transistor T2, a drain of the third nMOS transistor T3 is connected to a reading circuit (not shown) via a signal line, and a gate of the third nMOS transistor T3 is connected to a row selection line for supply of a selection signal SLCT. Thus, the first nMOS transistor T1 is called a reset transistor Rx, the second nMOS transistor T2 is called a drive transistor Dx, and the third nMOS transistor T3 is called a select transistor Sx.

The unit pixel of the general 3T type CMOS image sensor, as shown in FIG. 2, is defined with an active area 10. A single photodiode 20 is formed over a large-width portion of the active area 10, and gate electrodes 120, 130 and 140 of three overlapping transistors are formed over the remaining portion of the active area 10. Specifically, the reset transistor Rx is formed by the gate electrode 120, the drive transistor Dx is formed by the gate electrode 130, and the select transistor Sx is formed by the gate electrode 140. Here, dopant ions are implanted into the active area 10 of the respective transistors except for underneath each of the gate electrodes 120, 130 and 140, thus forming source/drain regions of the respective transistors. Thus, a power voltage Vdd is applied to the source/drain region between the reset transistor Rx and the drive transistor Dx, and the source/drain region at one side of the select transistor Sx is connected to the reading circuit. Although not shown in the drawing, the above-described gate electrodes 120, 130 and 140 are connected respectively to signal lines, and each signal line is provided at an end thereof with a pad to be connected to an external drive circuit.

FIG. 3 is a sectional view illustrating a related CMOS image sensor. As shown in FIG. 3, a P-type epitaxial layer 101 is grown over a P++ type semiconductor substrate 100 in which a device isolation area and an active area (including a photodiode area and a transistor area) are defined. A field oxide film 102 for separation between Green, Red and Blue light input regions is formed in the device isolation area of the semiconductor substrate 100. N-type diffusion regions 103 are formed in the photodiode area of the semiconductor substrate 100.

Next, gate electrodes 105 are formed in the transistor area of the semiconductor substrate 100 with a gate insulating film 104 interposed therebetween. An insulating film sidewall 106 is formed at opposite side surfaces of each gate electrode 105.

A first interlayer insulating film 108 is formed over an entire surface of the semiconductor substrate 100 including the gate electrodes 105, and various metal wirings 109 are formed over the first interlayer insulating film 108 with a predetermined interval therebetween.

A second interlayer insulating film 110 is formed with a thickness of approximately 4,000 Å over the entire surface of the semiconductor substrate 100 including the metal wirings 109. A nitride film 111 is formed over the second interlayer insulating film 110. Red, green and blue color filter layers 112 are formed over the nitride film 111, to correspond to the respective N-type diffusion regions 103.

A flattening layer 113 is formed over the entire surface of the semiconductor substrate 100 including the respective color filter layers 112. Micro-lenses 114 are formed over the flattening layer 113, to correspond to the respective color filter layers 112. Here, reference numeral 107 designates source and drain dopant regions of transistors.

In the CMOS image sensor described above, to achieve a higher sensitivity, no gap must be allowed between the micro-lenses 114 during the patterning of the microlenses 114. However, in practical applications, it is difficult to obtain a “zero gap” (i.e., no gap, or a gap with no width) between the micro-lenses 114. This is because reducing a gap between the micro-lenses 114 for realization of the zero gap may cause a bridge between the micro-lenses 114, thus resulting in a defocusing error of the micro-lenses 114 and deterioration of other properties. At present, a gap between the micro-lenses 114 is several tens of micrometers.

### SUMMARY

Embodiments relate to a semiconductor device, and more particularly, to a CMOS image sensor and a method for manufacturing the sensor. Embodiments relate to a CMOS image sensor and a method for manufacturing the same, in which a gap between micro-lenses is minimized, thus resulting in enhanced performance of the CMOS image sensor.

Embodiments relate to a method for manufacturing a CMOS image sensor which may include forming an interlayer insulating film over a semiconductor substrate in which a plurality of photodiodes are formed, forming a plurality of color filter layers corresponding to the photodiodes over the interlayer insulating film, forming a flattening layer over an entire surface of the semiconductor substrate including the respective color filter layers, forming gap insulating films over the flattening layer and over boundaries of the color filter layers, and forming micro-lenses over the flattening layer between the gap insulating films, to correspond to the respective photodiodes.

Embodiments relate to a CMOS image sensor which may include an interlayer insulating film formed over a semiconductor substrate in which a plurality of photodiodes are formed, a plurality of color filter layers formed over the interlayer insulating film, a flattening layer formed over an entire surface of the semiconductor substrate including the respective color filter layers, gap insulating films formed over the flattening layer and over boundaries of the color filter layers, and micro-lenses formed over the flattening layer between the gap insulating films, to correspond to the respective photodiodes.

### DRAWINGS

FIG. 1 is an equivalent circuit diagram of a general 3T type CMOS image sensor.

FIG. 2 is a lay-out diagram illustrating a unit pixel of the general 3T type CMOS image sensor.

FIG. 3 is a sectional view illustrating a related CMOS image sensor.

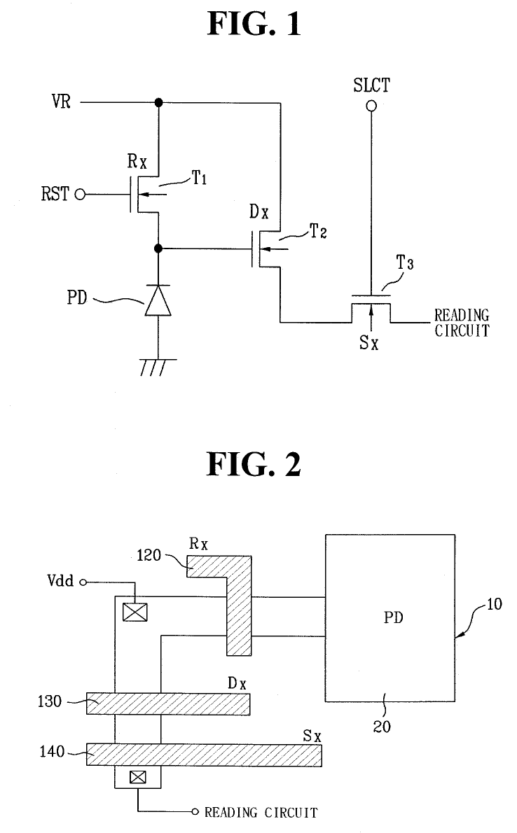

Example FIGS. 4A to 4F are process sectional views illustrating a method for manufacturing a CMOS image sensor according to embodiments.

### DESCRIPTION

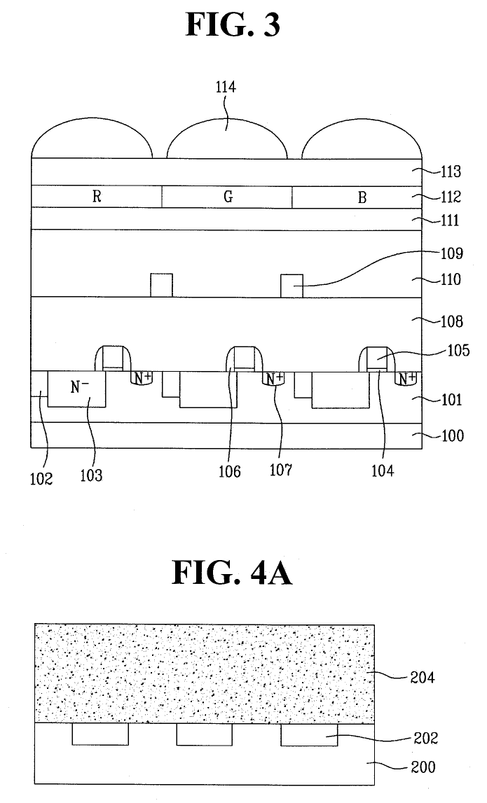

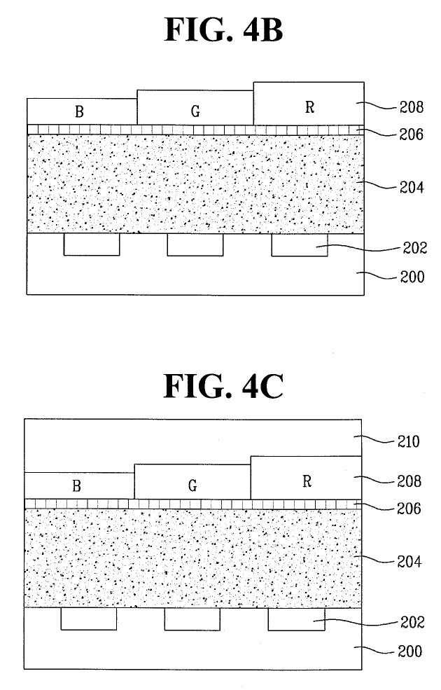

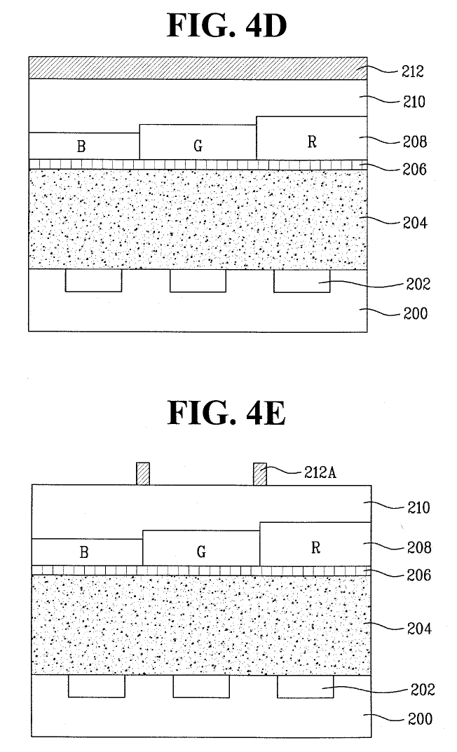

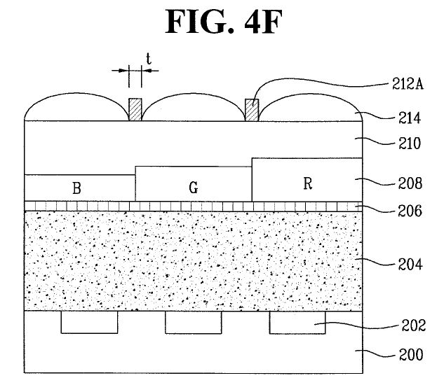

Example FIGS. 4A to 4F are process sectional views illustrating a method for manufacturing a CMOS image sensor according to embodiments. Referring to example FIG. 4A, an interlayer insulating film 204 may be formed over a semiconductor substrate 200 in which a plurality of photodiodes 202 is formed. Here, the semiconductor substrate 200 may be defined with a device isolation area and an active area and in turn, the active area may be defined with a photodiode area and a transistor area. The plurality of photodiodes 202 is formed in the photodiode area. The photodiodes 202 and various transistors are shown in a very simplified configuration, and a detailed description thereof will be omitted herein because it is well known in the art. The photodiodes 202 and transistors may be embodied in various configurations, for example, ones as shown in FIG. 3. Here, the interlayer insulating film 204 may be formed by use of any one of undoped silicate glass (USG), phosphor silicate glass (PSG), boron silicate glass (BSG), and boron phosphor silicate glass (BPSG).

Then, referring to example FIG. 4B, a protective film 206 may be formed over the interlayer insulating film 204. The protective film 206 serves to protect a device from moisture and scratches. After forming the protective film 206, a plurality of red, blue and green color filter layers 208 may be formed over the protective film 206, to correspond to the respective photodiodes 202. For example, after coating an entire surface of the protective film 206 with a flammable resist, exposure and developing processes may be carried out thus forming the color filter layers 208 which selectively filter light over a range of wavelengths. Here, the protective film 206 may be omitted. In this case, the plurality of color filter layers 208 are formed over the interlayer insulating film 204. The color filter layers 208, as shown in example FIG. 4B, may have different thicknesses from one another. Therefore, a flattening process, such as, for example, a chemical mechanical polishing (CMP) process, may be carried out.

Next, as shown in example FIG. 4C, a flattening layer 210 may be formed over the entire surface of the semiconductor substrate 200 including the respective color filter layers 208. As shown in example FIGS. 4D and 4E, gap insulating films 212A may be formed over the flattening layer 210 over boundaries of the color filter layers 208. Specifically, the gap insulating films 212A may be formed respectively over the boundary between the blue color filter layer and the green color filter layer and the boundary between the green color filter layer and the red color filter layer.

More specifically, an oxide film 212 may be deposited over an entire surface of the flattening layer 210. The oxide film 212 may be subjected to photographing and etching processes, thus forming an oxide film 212A as the gap insulating films 212A with a minimal width in gaps between spaces for formation of micro-lenses 214. In embodiments, a width “t” of the gap insulating films 212A may be minimized within an allowable Critical Dimension (CD) range with respect to masks used in the photographing and etching processes, and for example, may be 10 nm to 20 nm. In other words, the Critical Dimension, used as a standard of the design rules for the photolithographic processes used to make the CMOS sensor, may be used to determine the smallest possible width of the gap insulating films 212A used to separate the individual lenses as little as possible without forming bridges therebetween, or creating other problems.

Next, as shown in example FIG. 4F, the micro-lenses 214 may be formed over the flattening layer 210 between the gap insulating films 212A, to correspond to the respective photodiodes 202. For example, an upper surface of the flattening layer 210 may be coated with a photoresist for micro-lenses, and the coated photoresist may be selectively patterned by exposure and developing processes, thus forming a microlens pattern. The semiconductor substrate 200 over which the micro-lens pattern is formed may be put on a hot plate, and the semiconductor substrate 200 may be thermally processed at a temperature of, for example, 150° C. to 300° C., to cause reflow of the micro-lens pattern. With the reflow of the micro-lens pattern, semispherical micro-lenses 214 may be formed between the gap insulating films 212A. Subsequently, the micro-lenses 212 obtained by the thermal reflow may be subjected to a cooling process. The cooling process may be carried out in a state wherein the semiconductor substrate 200 is put on a cool plate.

Generally, if there is no gap between the neighboring micro-lenses 214 while applying heat to the micro-lens pattern, the heated reflowing photoresists may be colligated, causing malformation of the micro-lenses 214. This makes fabrication of micro-lenses having no gap difficult. However, in embodiments, malformation of the micro-lenses during thermal treatment may be prevented because the gap insulating films 212A are formed between regions for formation of the micro-lenses 214 prior to forming the micro-lenses 214.

Hereinafter, the overall configuration of the CMOS image sensor according to embodiments will be described with reference to example FIG. 4F. Referring to example FIG. 4F, the CMOS image sensor according to embodiments may include the semiconductor substrate 200, the plurality of photodiodes 202, the interlayer insulating film 204, the protective film 206, the plurality of color filter layers 208, the flattening layer 210, the gap insulating films 212A and the micro-lenses 214.

Here, the interlayer insulating film 204 may be formed over the semiconductor substrate 200 in which the plurality of photodiodes 202 are formed, and may take the form of a multilayer.

The flattened protective film 206, which, for example, may be used to protect a device from moisture and scratches, is formed over the interlayer insulating film 204. The plurality of color filter layers 208 may be formed over the protective film 206. Here, the protective film 206 may be selectively formed.

The flattening layer 210 may be formed over the entire surface of the semiconductor substrate 200 including the respective color filter layers 208. The gap insulating films 212A may be formed over the flattening layer 210 over the boundaries of the color filter layers 208. Here, the gap insulating films 212A may be formed of an oxide film. The micro-lenses 214 may be formed over the flattening layer 210 between the gap insulating films 212A, to correspond to the respective photodiodes 202.

As apparent from the above description, embodiments provide a CMOS image sensor and a method for manufacturing the sensor, in which a gap between micro-lenses is minimized, thus resulting in enhanced sensor characteristics. Further, even if the micro-lenses are increased in size due to, e.g., variations in processes, it may be possible to prevent a bridge between the neighboring micro-lenses and consequently, to preventing a defocusing error, etc.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer insulating film over a semiconductor substrate in which a plurality of photodiodes are formed;
forming a plurality of color filter layers corresponding to the photodiodes over the interlayer insulating film;
forming a flattening layer over an entire surface of the semiconductor substrate including the respective color filter layers;
forming gap insulating films over the flattening layer, and over boundaries of the color filter layers; and
forming micro-lenses over the flattening layer between the gap insulating films, to correspond to the respective photodiodes.

2. The method of claim 1, wherein the formation of the gap insulating films includes:
forming an oxide film over an entire surface of the flattening layer; and
patterning the oxide layer in gaps between the micro-lenses by performing photolithographic processes on the oxide film, to form the gap insulating films.

3. The method of claim 1, wherein a width of the gap insulating films is in a range of approximately 10 nm to 20 nm.

4. The method of claim 1, including forming a protective film over the interlayer insulating film, wherein the color filter layers are formed over the protective film.

5. The method of claim 1, wherein a width of the gap insulating films has a minimal value within an allowable Critical Dimension (CD) range.

6. The method of claim 1, including forming a CMOS image sensor using the semiconductor substrate, the plurality of photodiodes, the interlayer insulating film, the protective film, the plurality of color filter layers, the flattening layer, the gap insulating films and the micro-lenses.

7. The method of claim 1, wherein forming the microlenses includes forming the micro-lenses with photoresist.

8. The method of claim 7, wherein forming the microlenses with photoresist includes using a photolithographic process followed by a thermal reflow process.

9. An apparatus comprising:
an interlayer insulating film formed over a semiconductor substrate in which a plurality of photodiodes are formed;
a plurality of color filter layers formed over the interlayer insulating film;
a flattening layer formed over an entire surface of the semiconductor substrate including the respective color filter layers;
gap insulating films formed over the flattening layer, and over boundaries of the color filter layers; and
micro-lenses formed over the flattening layer between the gap insulating films, to correspond to the respective photodiodes.

10. The apparatus of claim 9, wherein a width of the gap insulating films is in a range of 10 nm to 20 nm.

11. The apparatus of claim 9, wherein the gap insulating films are formed of an oxide film.

12. The apparatus of claim 9, further comprising:
a protective film formed over the interlayer insulating film,
wherein the plurality of color filter layers are formed over the protective film.

13. The apparatus of claim 9, wherein a width of the gap insulating films has a minimal value within an allowable Critical Dimension (CD) range.

14. The apparatus of claim 9, wherein forming the microlenses includes forming the micro-lenses with photoresist.

15. The apparatus of claim 14, wherein forming the microlenses with photoresist includes using a photolithographic process followed by a thermal reflow process.

16. An apparatus configured to:
form an interlayer insulating film over a semiconductor substrate in which a plurality of photodiodes are formed;
form a plurality of color filter layers corresponding to the photodiodes over the interlayer insulating film;
form a flattening layer over an entire surface of the semiconductor substrate including the respective color filter layers;
form gap insulating films over the flattening layer, and over boundaries of the color filter layers; and
form micro-lenses over the flattening layer between the gap insulating films, to correspond to the respective photodiodes.

17. The apparatus of claim 16, configured to form the gap insulating films by:
forming an oxide film over an entire surface of the flattening layer; and
patterning the oxide layer in gaps between the micro-lenses by performing photolithographic processes on the oxide film, to form the gap insulating films.

18. The apparatus of claim 16, wherein a width of the gap insulating films is in a range of approximately 10 nm to 20 nm.

19. The apparatus of claim 16, configured to form a protective film over the interlayer insulating film, wherein the color filter layers are formed over the protective film.

20. The apparatus of claim 16, wherein a width of the gap insulating films has a minimal value within an allowable Critical Dimension (CD) range.
